(19) United States
(12) Patent Application Publication
(10) Pub. No.: US 2024/0172448 A1
(43) Pub. Date: May 23, 2024

(54) 3D FERROELECTRIC MEMORY DEVICE

(71) Applicant: Samsung Electronics Co., Ltd., Suwon-si (KR)

(72) Inventors: Seunggeol NAM, Suwon-si (KR); Jinseong HEO, Suwon-si (KR); Hyunjae LEE, Suwon-si (KR); Dukhyun CHOE, Suwon-si (KR)

(73) Assignee: Samsung Electronics Co., Ltd., Suwon-si (KR)

(21) Appl. No.: 18/492,130

(22) Filed: Oct. 23, 2023

(30) Foreign Application Priority Data
Nov. 21, 2022 (KR) 10-2022-0156764

(51) Int. Cl. H10B 51/20; H01L 21/28; H01L 29/51; H01L 29/78; H10B 51/10

(52) U.S. Cl. CPC H10B 51/20; H01L 29/40111; H01L 29/516; H01L 29/78391; H10B 51/10

(57) ABSTRACT

A three-dimensional (3D) ferroelectric memory device may include a substrate; a plurality of insulating layers stacked on the substrate; a plurality of gate electrodes between the plurality of insulating layers; a plurality of ferroelectric layers in contact with the plurality of gate electrodes; a plurality of intermediate electrodes in contact with the plurality of ferroelectric layers and protruding from side surfaces of the plurality of insulating layers; a gate insulating layer in contact with the plurality of intermediate electrodes and the plurality of insulating layers; and a channel layer in contact with the gate insulating layer.

### CROSS-REFERENCE TO RELATED APPLICATION

This application is based on and claims priority under 35 U.S.C. § 119 to Korean Patent Application No. 10-2022-0156764, filed on Nov. 21, 2022 in the Korean Intellectual Property Office, the disclosure of which is incorporated by reference herein in its entirety.

### BACKGROUND

### 1. Field

The disclosure relates to a three-dimensional (3D) ferroelectric memory device.

### 2. Description of the Related Art

Hard disks of the related art have been replaced by solid state drives (SSDs), and thus, NAND flash memory devices, which are non-volatile memory devices, have been widely commercialized. Recently, according to the miniaturization and high integration of memory devices, a 3D NAND flash memory device in which a plurality of memory cells are stacked in a direction perpendicular to a substrate has been developed.

Recently, research has been conducted to apply a ferroelectric field effect transistor (FeFET) having advantages, such as low operating voltage and fast programming speed, to a 3D NAND flash memory device.

### SUMMARY

Provided is a 3D ferroelectric memory device.

Additional aspects will be set forth in part in the description which follows and, in part, will be apparent from the description, or may be learned by practice of the presented embodiments of the disclosure.

According to an embodiment, a three-dimensional (3D) ferroelectric memory device may include a substrate, a plurality of insulating layers stacked on the substrate, a plurality of gate electrodes between the plurality of insulating layers, a plurality of ferroelectric layers in contact with the plurality of gate electrodes, a plurality of intermediate electrodes in contact with the plurality of ferroelectric layers, the plurality of intermediate layers protruding from side surfaces of the plurality of insulating layers, a gate insulating layer in contact with the plurality of intermediate electrodes and the plurality of insulating layers, and a channel layer in contact with the gate insulating layer.

In some embodiments, the plurality of gate electrodes may be stacked in a direction perpendicular to the substrate, and the plurality of gate electrodes each may extend in a direction parallel to the substrate.

In some embodiments, each of the plurality of gate electrodes may be electrically connected to a word line, and each of the plurality of intermediate electrodes may be a floating electrode.

In some embodiments, the plurality of intermediate electrodes may protrude and extend from side surfaces of the plurality of insulating layers in a first direction parallel to the substrate.

In some embodiments, the plurality of ferroelectric layers may include a corresponding ferroelectric layer. The plurality of gate electrodes may include a corresponding gate electrode in contact with the corresponding ferroelectric layer. The plurality of intermediate electrodes may include a corresponding intermediate electrode in contact with the corresponding ferroelectric layer. An area of the corresponding ferroelectric layer in contact with the gate electrode facing the corresponding intermediate electrode may be less than an area of the gate insulating layer in contact with the channel layer facing the corresponding intermediate electrode.

In some embodiments, a length of the corresponding ferroelectric layer in contact with the gate electrode opposite to the corresponding intermediate electrode may be less than a length of the gate insulating layer in contact with the channel layer opposite to the corresponding intermediate electrode.

In some embodiments, the plurality of ferroelectric layers may include a corresponding ferroelectric layer. The plurality of gate electrodes may include a corresponding gate electrode. The corresponding ferroelectric layer may be on an upper surface of the corresponding gate electrode, a lower surface of the corresponding gate electrode, and one side of the corresponding gate electrode. The lower surface of the corresponding gate electrode may be parallel to the substrate, and the one side of the corresponding gate electrode may be perpendicular to the substrate.

In some embodiments, the plurality of ferroelectric layers may include a corresponding ferroelectric layer. The plurality of gate electrodes may include a corresponding gate electrode. The corresponding ferroelectric layer may be on one side of the corresponding gate electrode. The one side of corresponding gate electrodes may be perpendicular to the substrate.

In some embodiments, the 3D ferroelectric memory device may further include a source electrode and a drain electrode spaced apart from each other on the channel layer in a second direction. The second direction may be parallel to the substrate and perpendicular to the first direction, respectively.

In some embodiments, the source electrode may be electrically connected to a source line, and the drain electrode may be electrically connected to a bit line.

In some embodiments, the plurality of gate electrodes and the plurality of intermediate electrodes each may independently include at least one of W, TiN, TaN, WN, NbN, Mo, Ru, Ir, RuO, IrO, and polysilicon.

In some embodiments, the insulating layer may include at least one of SiO, SiOC, SiON, and SiN.

In some embodiments, the plurality of ferroelectric layers may include a fluorite-based material, a nitride-based material, or a perovskite material.

In some embodiments, the gate insulating layer may include at least one of SiO, SiN, AlO, HfO, and ZrO.

In some embodiments, the channel layer may extend in a direction perpendicular to the substrate.

In some embodiments, the channel layer may be commonly connected to the plurality of gate electrodes such that the channel layer faces the plurality of gate electrodes.

In some embodiments, the channel layer may include a Group IV semiconductor, a Group III-V semiconductor, an oxide semiconductor, a nitride semiconductor, a nitride semiconductor, a 2D semiconductor material, a quantum dot, or an organic semiconductor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a three-dimensional (3D) ferroelectric memory device according to an embodiment;

FIG. 2 is a cross-sectional view taken along line II-II′ of FIG. 1;

FIG. 3 shows a portion A of the 3D ferroelectric memory device according to an embodiment shown in FIG. 2;

FIG. 4 is an enlarged cross-sectional view of one ferroelectric field effect transistor in the 3D ferroelectric memory device shown in FIG. 3;

FIG. 5 is a cross-sectional view of a 3D ferroelectric memory device according to another embodiment;

FIG. 6 is an enlarged view of a portion of FIG. 5;

FIGS. 7 to 17 are diagrams for explaining a method of manufacturing a 3D ferroelectric memory device according to an embodiment;

FIG. 18 is a conceptual diagram schematically illustrating a device architecture applicable to an electronic device according to an embodiment; and

FIG. 19 is a block diagram of an electronic device according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereafter, the disclosure will be described more fully with reference to the accompanying drawings. In the drawings, like reference numerals refer to like elements throughout, and sizes of elements in the drawings may be exaggerated for clarity and convenience of explanation. The embodiments of the disclosure are capable of various modifications and may be embodied in many different forms.

It will be understood that when an element or layer is referred to as being “on” or “above” another element or layer, the element or layer may be directly on/under/left/right another element or layer or intervening elements on/under/left/right or layers. The singular forms “a,” “an” and “the” are intended to include the plural forms as well, unless the context clearly indicates otherwise. When a portion “includes” an element, another element may be further included, rather than excluding the existence of the other element, unless otherwise described.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members can be represented by replaceable or additional various functional connections, physical connections, or circuit connections in an actual apparatus.

The use of any and all examples, or example language provided herein, is intended merely to better illuminate the disclosure and does not pose a limitation on the scope of the disclosure unless otherwise claimed.

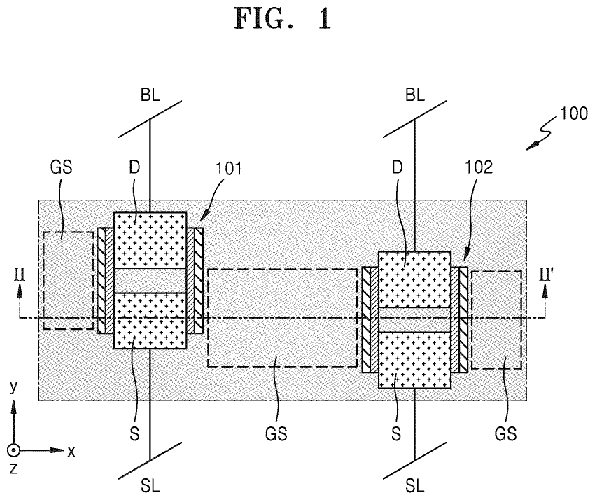

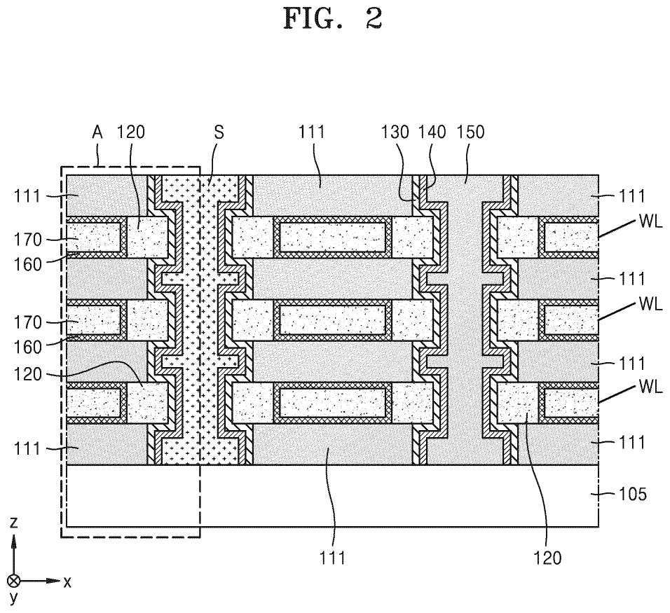

FIG. 1 is a plan view of a three-dimensional (3D) ferroelectric memory device 100 according to an embodiment. FIG. 2 is a cross-sectional view taken along line II-II′ of FIG. 1.

Referring to FIGS. 1 and 2, the 3D ferroelectric memory device 100 includes a plurality of vertically stacked structures 101 and 102 spaced apart from each other on a substrate 105. In FIG. 1, the two vertically stacked structures 101 and 102 are shown as an example. However, the 3D ferroelectric memory device 100 may include various numbers of vertically stacked structures.

Each of the vertically stacked structures 101 and 102 may include a plurality of memory cells stacked in a direction perpendicular to the substrate 105, and each memory cell may include a ferroelectric field effect transistor (FeFET) having a metal ferroelectric metal insulator semiconductor (MFMIS) structure as will be described later.

The substrate 105 may include various materials. For example, the substrate 105 may include a single crystal silicon substrate, a compound semiconductor substrate, or a silicon on insulator (SOI) substrate. However, this is merely an example, and other substrates 105 including various materials may be used. In addition, the substrate 105 may further include, for example, an impurity region doped with a dopant, an electronic device, such as a transistor, or a peripheral circuit for selecting and controlling memory cells that store data.

A plurality of ferroelectric field effect transistors are stacked in a direction perpendicular to a surface of the substrate 105 (z-axis direction). Here, each ferroelectric field effect transistor may have an MFMIS structure. Specifically, each ferroelectric field effect transistor includes a gate electrode 170, a ferroelectric layer 160, an intermediate electrode 120, a gate insulating layer 130, and a channel layer 140 sequentially provided in a first direction (x-axis direction) parallel to the surface of the substrate 105. Each gate electrode 170 is electrically connected to a word line (see WL in FIG. 2), and a desired and/or alternatively predetermined voltage may be applied to each gate electrode 170 through the word line.

The channel layer 140 may be provided extending in a direction (z-axis direction) perpendicular to the surface of the substrate 105. The channel layer 140 may be provided in common to correspond to a plurality of ferroelectric field effect transistors. A source electrode S and a drain electrode D are spaced apart from each other on both sides of the channel layer 140 in a second direction (y-axis direction) parallel to the surface of the substrate 105 and perpendicular to the first direction (x-axis direction). A filling insulating layer 150 may fill an area between the source electrode S and the drain electrode D.

Each source electrode S may be electrically connected to a source line (see SL in FIG. 1), and each drain electrode D may be electrically connected to a bit line (see bit line BL in FIG. 1). The channel layer 140 between the source electrode S and the drain electrode D may form a channel of each ferroelectric field effect transistor. A channel of each ferroelectric field effect transistor may be parallel to the surface of the substrate 105. As shown in FIGS. 1-2, gate stacks GS may be under the uppermost insulating layer 111. The gate stack GS may refer to a plurality of units spaced apart from each other in a direction (z-axis direction), where each unit may include a gate electrode 170, ferroelectric layer 160, and intermediate electrode 120.

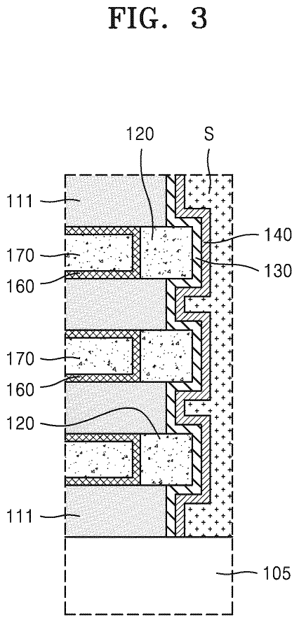

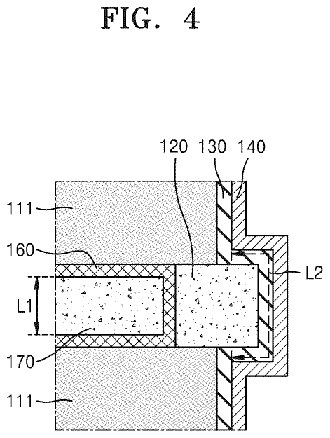

FIG. 3 shows a portion A of the 3D ferroelectric memory device 100 according to the embodiment shown in FIG. 2. FIG. 4 is an enlarged view of a cross section of one ferroelectric field effect transistor.

Referring to FIGS. 3 and 4, a plurality of insulating layers 111 are stacked in a direction perpendicular to the substrate 105 (z-axis direction), and a plurality of gate electrodes 170 are stacked between the plurality of insulating layers 111. The plurality of gate electrodes 170 may be stacked in a direction perpendicular to the substrate 105 (z-axis direction), and each of the gate electrodes 170 may extend in a direction parallel to the substrate 105. Here, each gate electrode 170 may be recessed in a direction parallel to the substrate 105 from side surfaces of adjacent insulating layers 111.

The insulating layer 111 is for insulating between the gate electrodes 170 and may include, for example, at least one of SiO, SiOC, and SiON. However, the insulating layer 111 is not limited thereto. A thickness of the insulating layer 111 may be in a range from about 7 nm to about 100 nm, but this is an example.

The gate electrode 170 may include a conductive material, such as a metal, a metal nitride, a metal oxide, or polysilicon. For example, the gate electrode 170 may include at least one of W, TiN, TaN, WN, NbN, Mo, Ru, Ir, RuO, IrO, and highly doped polysilicon. However, this is just an example, and besides above, the gate electrode 170 may include various other conductive materials. The gate electrode 170 may have a thickness, for example, in a range from about 5 nm to about 100 nm, but is not limited thereto.

The ferroelectric layer 160 is provided on each gate electrode 170. The ferroelectric layer 160 may be provided to contact the gate electrode 170. Specifically, the ferroelectric layer 160 may be provided on upper and lower surfaces of the gate electrode 170 parallel to the substrate 105 and on one side of the gate electrode 170 perpendicular to the substrate 105. In other words, the ferroelectric layer 160 may extend from one side of the gate electrode 170 to cover upper and lower surfaces of the gate electrode 170. Upper and lower surfaces of the ferroelectric layer 160 may contact the insulating layer 111.

Ferroelectric materials have a spontaneous dipole (electric dipole) due to non-centrosymmetric charge distribution, that is, spontaneous polarization, in a unit cell in a crystallized material structure. In addition, ferroelectric materials have remnant polarization by dipoles even in the absence of an external electric field. Also, in ferroelectric materials, the direction of polarization may be switched in unit of domain by an external electric field.

The ferroelectric layer 160 may include, for example, a fluorite-based material, a nitride-based material, or perovskite. The nitride-based material may include, for example, AlScN, and the perovskite may include, for example, PZT, BaTiO₃, PbTiO₃, and the like. However, it is not limited thereto.

A fluorite-based material may include, for example, an oxide of at least one selected from Hf, Si, Al, Zr, Y, La, Gd, and Sr. As a specific example, the ferroelectric layer 160 may include at least one of hafnium oxide (HfO), zirconium oxide (ZrO), and hafnium-zirconium oxide (HfZrO). Hafnium oxide (HfO), zirconium oxide (ZrO), and hafnium-zirconium oxide (HfZrO) constituting the ferroelectric layer 160 may have a crystal structure of an orthorhombic crystal system. The ferroelectric layer 160 may further include, for example, at least one dopant selected from among Si, Al, La, Y, Sr, and Gd. The thickness of the ferroelectric layer 160 provided on the gate electrode 170 may be in a range from about 3 nm to about 20 nm, but this is merely an example.

The intermediate electrode 120 as a floating electrode is provided on each ferroelectric layer 160. The intermediate electrode 120 may be provided to contact one side of the ferroelectric layer 160.

The intermediate electrode 120 may include a conductive material like the gate electrode 170. For example, the intermediate electrode 120 may include at least one of W, TiN, TaN, WN, NbN, Mo, Ru, Ir, RuO, IrO, and polysilicon. The intermediate electrode 120 may include the same conductive material as the gate electrode 170 or a different conductive material from the gate electrode 170.

Each intermediate electrode 120 may protrude from side surfaces of adjacent insulating layers 111 in the first direction (x-axis direction) parallel to the surface of the substrate 105. The thickness of the intermediate electrode 120 may be a distance between adjacent insulating layers 111. If the thickness of the gate electrode 170 is t1 and the thickness of the ferroelectric layer 160 is t2, the thickness t3 of the intermediate electrode 120 may be t1+2·t2.

The gate insulating layer 130 may be provided to contact side surfaces of the insulating layers 111 and side surfaces of the intermediate electrodes 120. The gate insulating layer 130 may be provided to extend in a direction (z-axis direction) perpendicular to the substrate 105. The gate insulating layer 130 may have a curved shape by the intermediate electrodes 120 protruding from the side surfaces of the insulating layers 111 in a first direction (x-axis direction) parallel to the surface of the substrate 105.

The gate insulating layer 130 may include, for example, at least one of SiO, SiN, AlO, HfO, and ZrO, but is not limited thereto. The gate insulating layer 130 may have a thickness in a range from about 1 nm to about 10 nm, but this is an example.

The channel layer 140 may be provided to contact the gate insulating layer 130. The gate insulating layer 130 and the channel layer 140 may be sequentially stacked in the first direction (x-axis direction) parallel to the surface of the substrate 105. The channel layer 140 may have a curved shape corresponding to the gate insulating layer 130. The channel layer 140 may be provided in a direction perpendicular to the substrate 105 (z-axis direction) corresponding to the plurality of gate electrodes 170. Accordingly, a plurality of ferroelectric field effect transistors stacked in a direction perpendicular to the substrate 105 may share one channel layer 140.

The channel layer 140 may include a semiconductor material. For example, the channel layer 140 may include a Group IV semiconductor or a Group III-V semiconductor, such as Si, Ge, or SiGe. Also, the channel layer 140 may include, for example, an oxide semiconductor, a nitride semiconductor, a nitride semiconductor, a two-dimensional (2D) semiconductor material, a quantum dot, or an organic semiconductor. Here, the oxide semiconductor may include, for example, InGaZnO, and the like, the 2D semiconductor material may include, for example, transition metal dichalcogenide (TMD) or graphene, and the quantum dots may include colloidal QDs, or a nanocrystal structure and the like. However, this is only an example, and the embodiment is not limited thereto.

The channel layer 140 may further include a dopant. Here, the dopant may include a p-type dopant or an n-type dopant. The p-type dopant may include, for example, a Group III element such as B, Al, Ga, and In, and the n-type dopant may include a Group V element, such as P, As, and Sb. The channel layer 140 may have a thickness in a range from about 1 nm to about 20 nm, but is not limited thereto.

A source electrode S and a drain electrode D are spaced apart from each other on both sides of the channel layer 140 in a second direction (y-axis direction) parallel to the surface of the substrate 105, and between the source electrode S and the drain electrode D may be filled with the filling insulating layer 150. The channel layer 140 between the source electrode S and the drain electrode D may form a channel of each ferroelectric field effect transistor.

In each ferroelectric field effect transistor, a ferroelectric polarization direction may be determined according to a gate voltage applied to the gate electrode 120, and thus, a memory operation may be performed. Here, in order to perform a non-volatile memory operation, a gate voltage higher than a coercive field in which ferroelectric polarization switching occurs may be applied to the gate electrode 120.

In a ferroelectric field effect transistor of a general MFMIS structure, when a gate insulating layer has a relatively low capacitance compared to the ferroelectric layer and a high voltage is applied to the gate electrode to change the polarization of the ferroelectric materials, a high electric field is applied to the gate insulating layer, and thus, a breakdown may occur, and accordingly, the gate insulating layer may be deteriorated. Therefore, in order to limit and/or prevent deterioration of the gate insulating layer, it may be necessary for the gate insulating layer to have a relatively high capacitance compared to the ferroelectric layer.

In the embodiment, a ratio of the capacitance of the gate insulating layer 130 to the capacitance of the ferroelectric layer 160 is proportional to a ratio of a second area of the gate insulating layer 130 in contact with the channel layer 140 to a first area of the ferroelectric layer 160 in contact with the gate electrode 170. Here, the first area of the ferroelectric layer 160 may denote an area where the gate electrode 170 facing the intermediate electrode 120 contacts the ferroelectric layer 160, and the second area of the gate insulating layer 130 may denote an area where the channel layer 140 facing the intermediate electrode 120 contacts the gate insulating layer 130.

Referring to FIG. 4, a ratio of the second area of the gate insulating layer 130 in contact with the channel layer 140 to the first area of the ferroelectric layer 160 in contact with the gate electrode 170 is proportional to a ratio of a second length L2 of the gate insulating layer 130 in contact with the channel layer 140 to a first length L1 of the ferroelectric layer 160 in contact with the gate electrode 170. Here, the first length L1 of the ferroelectric layer 160 means a length at which the gate electrode 170 facing the intermediate electrode 120 contacts the ferroelectric layer 160. The first length L1 of the ferroelectric layer 160 may correspond to a thickness of the gate electrode 170. Alternatively, if the thickness of the ferroelectric layer 160 is t2 and the thickness of the intermediate electrode 120 is t3, the first length L1 of the ferroelectric layer 160 may be t3−2·t2. The second length L2 of the gate insulating layer 130 means a length at which the gate insulating layer 130 contacts the channel layer 140 facing the protruding intermediate electrode 120.

In the embodiment, the intermediate electrode 120 is provided to protrude from side surfaces of adjacent insulating layers 111, and the gate insulating layer 130 and the channel layer 140 are sequentially provided on the protruding intermediate electrode 120, to increase the second length L2 of the gate insulating layer 130 in contact with the channel layer 140 to the first length L1 of the ferroelectric layer in contact with the gate electrode 170. Accordingly, the ratio of the second area of the gate insulating layer 130 in contact with the channel layer 140 to the first area of the ferroelectric layer 160 in contact with the gate electrode 170 may be increased, and a ratio of the capacitance of the gate insulating layer 130 to the capacitance of the gate electrode 170 may be increased.

In this way, the intensity of an electric field applied to the gate insulating layer 130 may be reduced by increasing the ratio of the capacitance of the gate insulating layer 130 to the capacitance of the ferroelectric layer 170. Accordingly, an operating voltage may be reduced, an operating speed may be increased, and the reliability of the 3D ferroelectric memory device 100 may be improved by limiting and/or preventing deterioration of the gate insulating layer 130. In addition, on-current may be improved by increasing a width of the channel layer 140 facing the intermediate electrode 120.

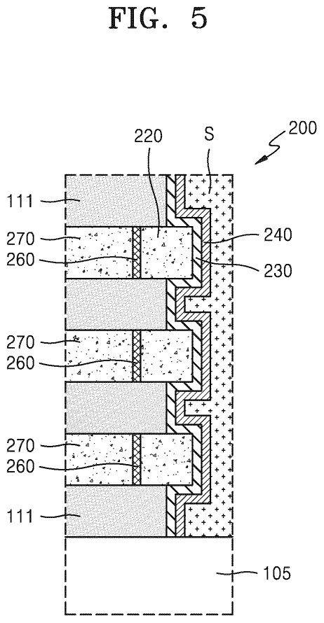

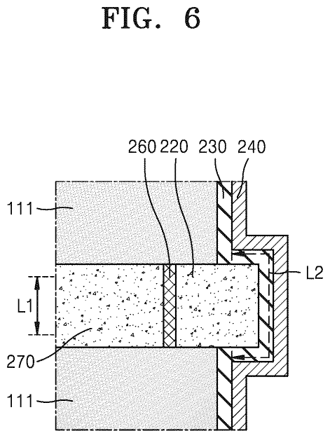

FIG. 5 is a cross-sectional view of a 3D ferroelectric memory device 200 according to another embodiment. FIG. 6 is an enlarged view of a portion of the 3D ferroelectric memory device 200 of FIG. 5. Hereinafter, differences from the embodiment described above will be mainly described.

Referring to FIGS. 5 and 6, a plurality of insulating layers 111 are stacked in a direction perpendicular to a substrate 105 (z-axis direction), and a plurality of gate electrodes 270 are stacked between the plurality of insulating layers 111. The plurality of gate electrodes 270 may be stacked in a direction perpendicular to the substrate 105 (z-axis direction), and each gate electrode 270 may extend in a direction parallel to the substrate 105. Here, each gate electrode 270 may be provided to be recessed in the first direction (x-axis direction) parallel to the substrate 105 from side surfaces of adjacent insulating layers 111. The insulating layer 111 may include, for example, at least one of SiO, SiOC, and SiON, and the gate electrode 270 may include, for example, a conductive material, such as a metal, a metal nitride, a metal oxide, or polysilicon.

A ferroelectric layer 260 is provided on each gate electrode 270. The ferroelectric layer 260 may be provided in contact with one side of the gate electrode 270 perpendicular to the substrate 105. The ferroelectric layer 260 may include, for example, a fluorite-based material, a nitride-based material, or perovskite.

An intermediate electrode 220 as a floating electrode is provided on each ferroelectric layer 260. The intermediate electrode 220 may be provided to contact the ferroelectric layer 260. The intermediate electrode 220 may include a conductive material like the gate electrode 270. Each intermediate electrode 220 may protrude from side surfaces of adjacent insulating layers 111 in the first direction (x-axis direction) parallel to the surface of the substrate 105. Here, a thickness of the intermediate electrode 220 may be a thickness of the gate electrode 270.

The gate insulating layer 230 may be provided to contact side surfaces of the insulating layers 111 and side surfaces of the intermediate electrodes 220. The gate insulating layer 230 may be provided to extend in a direction (z-axis direction) perpendicular to the substrate 105. The gate insulating layer 230 may have a curved shape by the intermediate electrodes 220 protruding from the side surfaces of the insulating layers 111 in the first direction (x-axis direction) parallel to the surface of the substrate 105. The gate insulating layer 230 may include, for example, at least one of SiO, SiN, AlO, HfO, and ZrO, but is not limited thereto.

The channel layer 240 may be provided to contact the gate insulating layer 230. The channel layer 240 may have a curved shape corresponding to the gate insulating layer 230. For example, the channel layer 240 may include a Group IV semiconductor or a Group III-V semiconductor such as Si, Ge, or SiGe. Also, the channel layer 240 may include, for example, an oxide semiconductor, a nitride semiconductor, a nitride semiconductor, a 2D semiconductor material, a quantum dot, or an organic semiconductor. The channel layer 240 may further include a dopant.

Referring to FIG. 6, a ratio of a second area of the gate insulating layer 230 in contact with the channel layer 240 to a first area of the ferroelectric layer 260 in contact with the gate electrode 270 is proportional to a ratio of a second length L2 of the gate insulating layer 230 in contact with the channel layer 240 to a first length L1 of the ferroelectric layer 260 in contact with the gate electrode 270. Here, the first length L1 of the ferroelectric layer 260 means a length at which the gate electrode 270 facing the intermediate electrode 220 contacts the ferroelectric layer 260. The first length L1 of the ferroelectric layer 260 may be the thickness of the gate electrode 270 or the thickness of the intermediate electrode 220. The second length L2 of the gate insulating layer 230 means a length at which the gate insulating layer 230 contacts the channel layer 240 facing the protruding intermediate electrode 220.

The intermediate electrode 220 is provided to protrude from the side surfaces of the adjacent insulating layers 111, and the gate insulating layer 230 and the channel layer 240 are sequentially provided on the protruding intermediate electrode 220, and thus, the second length L2 of the gate insulating layer 230 in contact with the channel layer 240 to the first length L1 of the ferroelectric layer in contact with the gate electrode 270 may be increased. Accordingly, the ratio of the second area of the gate insulating layer 230 in contact with the channel layer 240 to the first area of the ferroelectric layer 260 in contact with the gate electrode 270 may be increased, and a ratio of the capacitance of the gate insulating layer 230 to the capacitance of the gate electrode 270 may be increased.

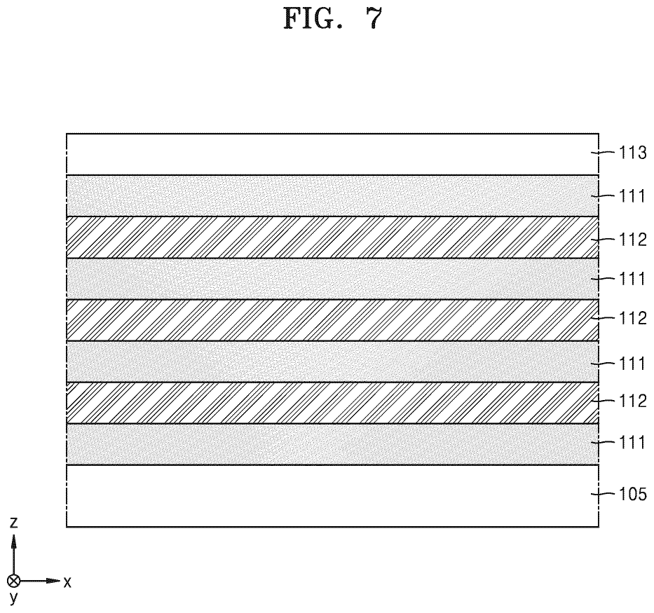

FIGS. 7 to 17 are diagrams for explaining a method of manufacturing a 3D ferroelectric memory device 100 according to an embodiment. FIGS. 7 to 17 illustrate a manufacturing method of the 3D ferroelectric memory device 100 shown in FIG. 2 as an example.

Referring to FIG. 7, a plurality of first mold layers 111 and a plurality of second mold layers 112 are alternately stacked in a direction (z-axis direction) perpendicular to a substrate 105, and then a third mold layer 113 is stacked thereon. The substrate 105 may include various materials. For example, the substrate 105 may include a single crystal silicon substrate, a compound semiconductor substrate, or an SOI substrate. However, this is an example, and other substrates 105 including various materials may be used. In addition, the substrate 105 may further include, for example, an impurity region by doping, an electronic device, such as a transistor, or a peripheral circuit for selecting and controlling memory cells that store data.

The first mold layer 111 corresponds to the insulating layer 111 shown in FIG. 2 described above, and may include, for example, at least one of SiO, SiOC, and SiON, but is not limited thereto. The first mold layer 111 may be formed to a thickness of, for example, in a range from about 7 nm to about 100 nm, but this is an example.

The second mold layer 112 may include a material having etch selectivity with respect to the first mold layer 111. For example, the second mold layer 112 may include SiN, but is not limited thereto. The third mold layer 113 is provided for patterning the first and second mold layers 111 and 112 and may include a material having etching selectivity with respect to the first and second mold layers 111 and 112.

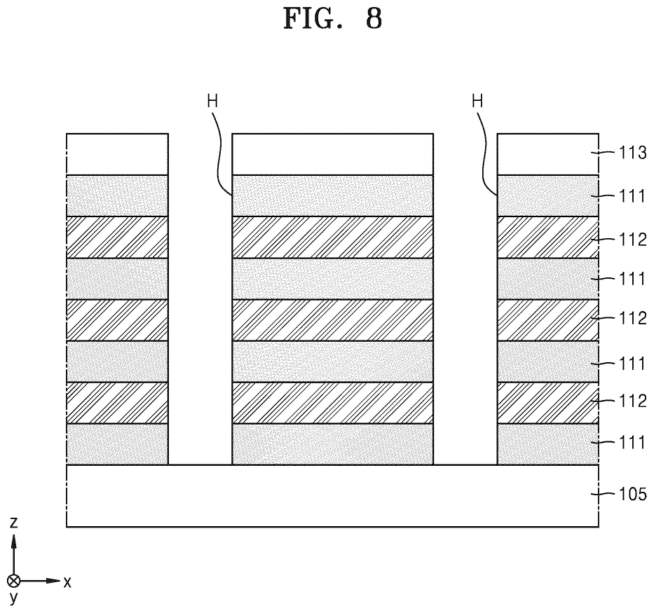

Referring to FIG. 8, after patterning the third mold layer 113, through-holes H penetrating the plurality of first mold layers 111 and the plurality of second mold layers 112 are formed by using the patterned third mold layer 113 as an etching mask. FIG. 8 shows a case in which two through holes H are formed as an example. The through hole H may extend in a direction perpendicular to the substrate 105 (z-axis direction). Side surfaces of the first and second mold layers 111 and 112 may be exposed through the through hole H.

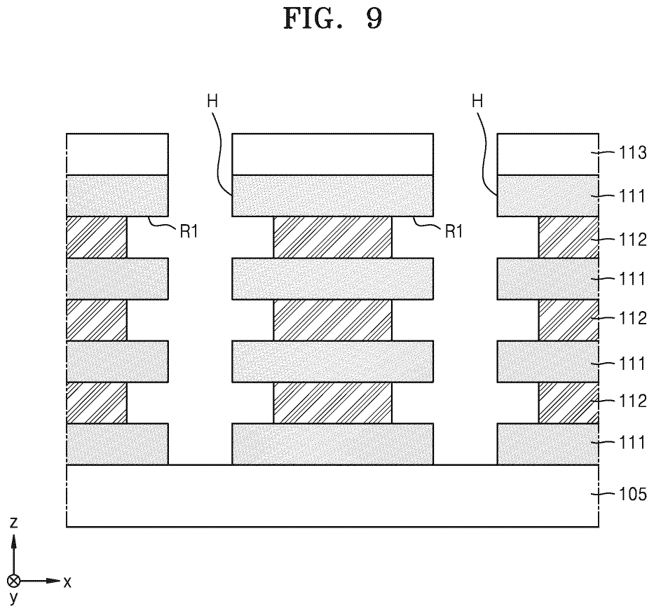

Referring to FIG. 9, first recesses R1 are formed by selectively etching the side surfaces of the second mold layers 112 exposed through the through hole H. Here, each first recess R1 may extend parallel to the surface of the substrate 105 from the side surface of the first mold layer 111 to a desired and/or alternatively predetermined depth.

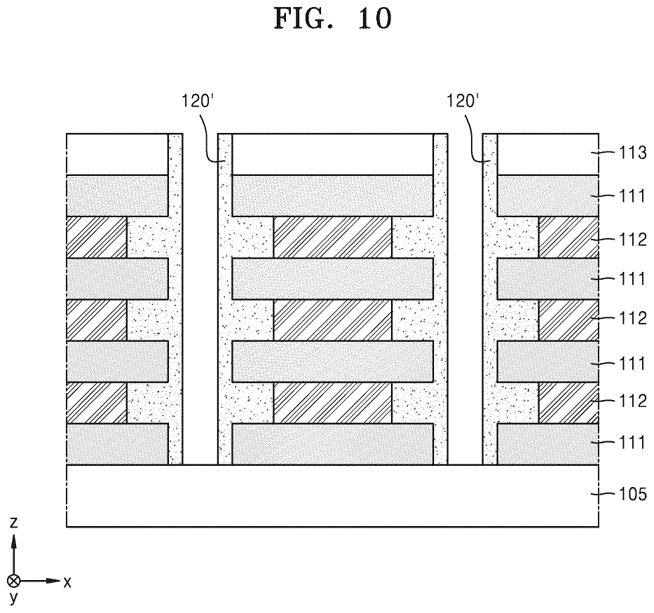

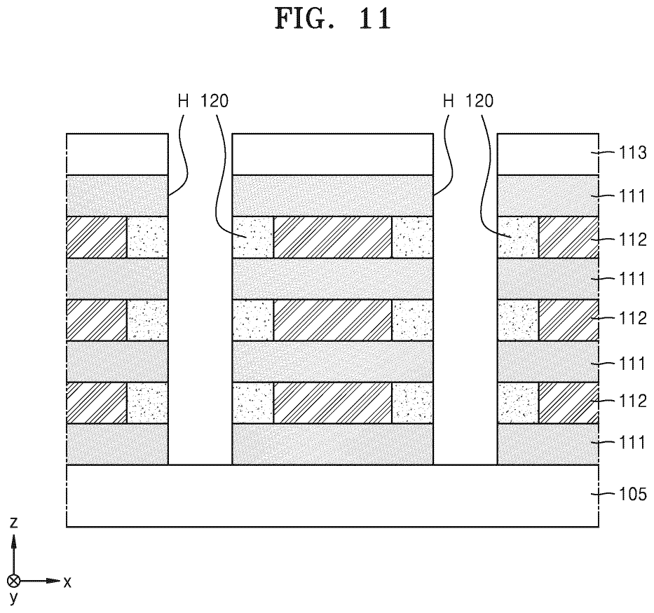

Referring to FIGS. 10 and 11, after forming an intermediate electrode layer 120′ to cover the side surfaces of the first mold layers 111 and the first recesses R1, a plurality of intermediate electrodes 120 are formed by etching the intermediate electrode layer 120′ until the side surface of the first mold layer 111 is exposed. Each intermediate electrode 120 may contact the side surface of the second mold layer 112 and may be provided to fill the first recess R1. The intermediate electrode 120 may include a conductive material, such as a metal, a metal nitride, a metal oxide, or polysilicon. For example, the intermediate electrode 120 may include at least one of W, TiN, TaN, WN, NbN, Mo, Ru, Ir, RuO, IrO, and highly doped poly silicon. However, this is only an example, and, in addition, the intermediate electrode 120 may include various other conductive materials.

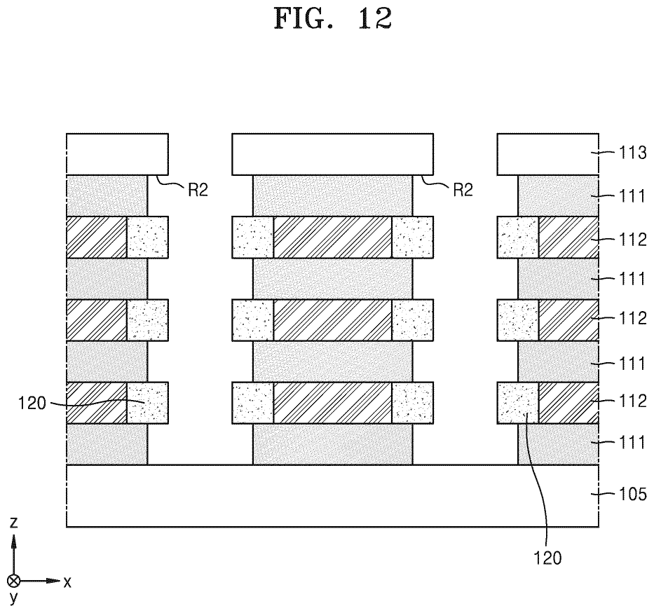

Referring to FIG. 12, second recesses R2 are formed by selectively etching side surfaces of the first mold layers 111 exposed through the through hole H. Here, each second recess R2 may extend parallel to the surface of the substrate 105 from the side surface of the intermediate electrode 120 to a desired and/or alternatively predetermined depth. Accordingly, the intermediate electrodes 120 may be provided to protrude from the side surfaces of the first mold layers 111 in the first direction (x-axis direction) parallel to the substrate 105.

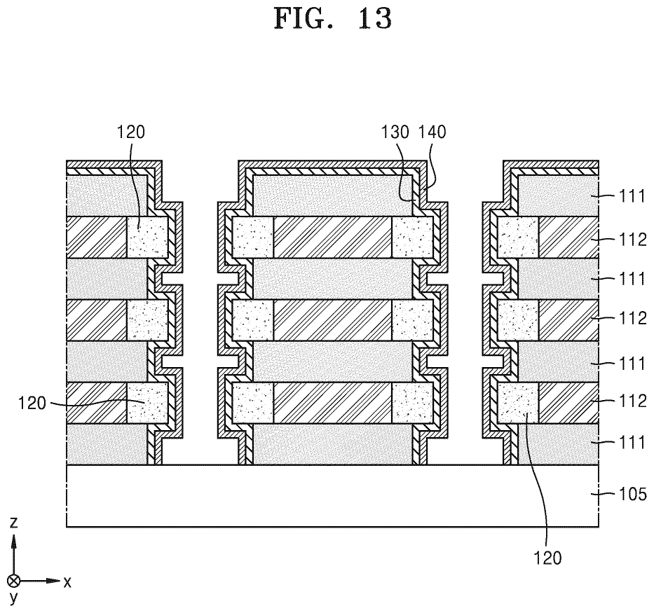

Referring to FIG. 13, after the third mold layer 113 is removed, a gate insulating layer 130 and a channel layer 140 are sequentially deposited on the surfaces of the first mold layers 111 and the intermediate electrodes 120, the gate insulating layer 130 and the channel layer 140 formed on an upper surface of the first mold layer 111 are removed. Accordingly, the gate insulating layer 130 and the channel layer 140 may be sequentially formed on the side surfaces of the first mold layers 111 and the intermediate electrodes 120 in contact with the through hole H in the first direction parallel to the substrate.

The gate insulating layer 130 may be provided to contact side surfaces of the first mold layers 111 and side surfaces of the intermediate electrodes 120. The gate insulating layer 130 may extend in a direction (z-axis direction) perpendicular to the substrate 105. The gate insulating layer 130 may have a curved shape by the intermediate electrodes 120 protruding from the side surfaces of the insulating layers 111 in the first direction (x-axis direction) parallel to the surface of the substrate 105. The gate insulating layer 130 may include, for example, at least one of SiO, SiN, AlO, HfO, and ZrO, but is not limited thereto.

The channel layer 140 may be provided to contact the gate insulating layer 130. The channel layer 140 may have a curved shape corresponding to the gate insulating layer 130. The channel layer 140 may extend in a direction perpendicular to the substrate 105 (z-axis direction).

The channel layer 140 may include a semiconductor material. For example, the channel layer 140 may include a Group IV semiconductor or a Group III-V semiconductor, such as Si, Ge, or SiGe. Also, the channel layer 140 may include, for example, an oxide semiconductor, a nitride semiconductor, a nitride semiconductor, a 2D semiconductor material, a quantum dot, or an organic semiconductor. Here, the oxide semiconductor may include, for example, InGaZnO, and the like, the two-dimensional semiconductor material may include, for example, transition metal dichalcogenide (TMD) or graphene, and the quantum dot may include colloidal QD, a nanocrystal structure, and the like. However, this is only an example, and the embodiment is not limited thereto.

The channel layer 140 may further include a dopant. Here, the dopant may include a p-type dopant or an n-type dopant. The p-type dopant may include, for example, a Group III element, such as B, Al, Ga, and In, and the n-type dopant may include a Group V element, such as P, As, and Sb.

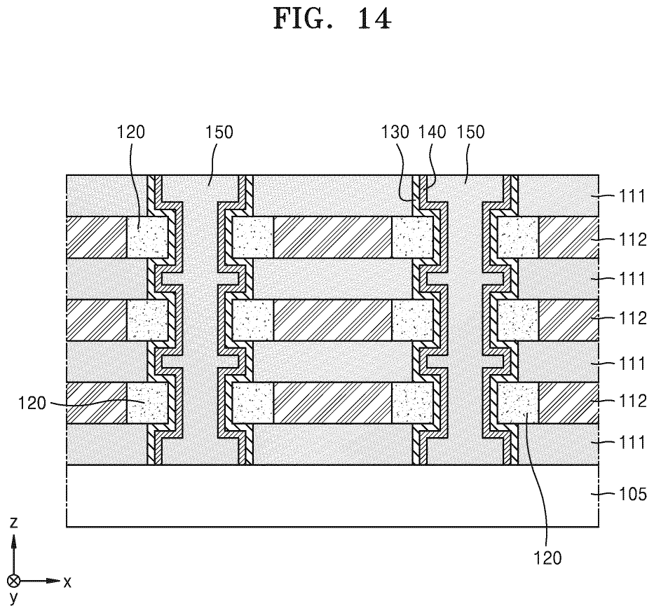

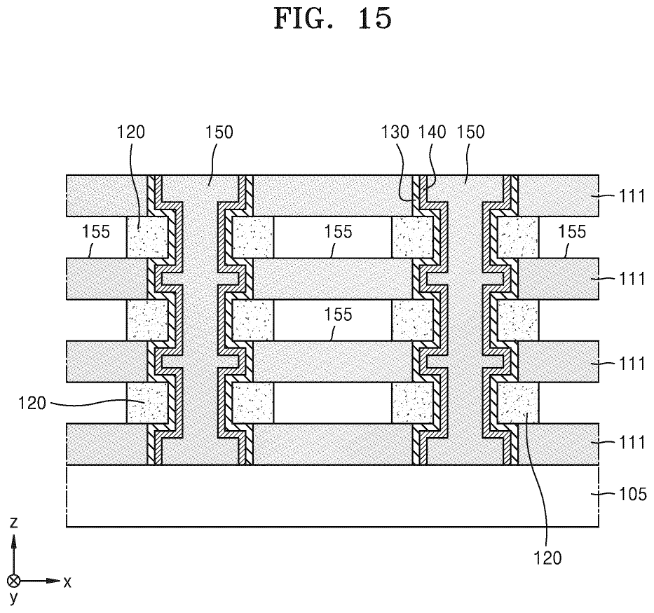

Referring to FIG. 14, a filling insulating layer 150 is formed to fill the through hole H. The filling insulating layer 150 may include, for example, various insulating materials, such as silicon oxide and silicon nitride. Referring to FIG. 15, empty spaces 155 are formed by selectively removing the second mold layers 112 by etching. Upper and lower surfaces of the first mold layers 111 and side surfaces of the intermediate electrodes 120 may be exposed by the empty spaces 155.

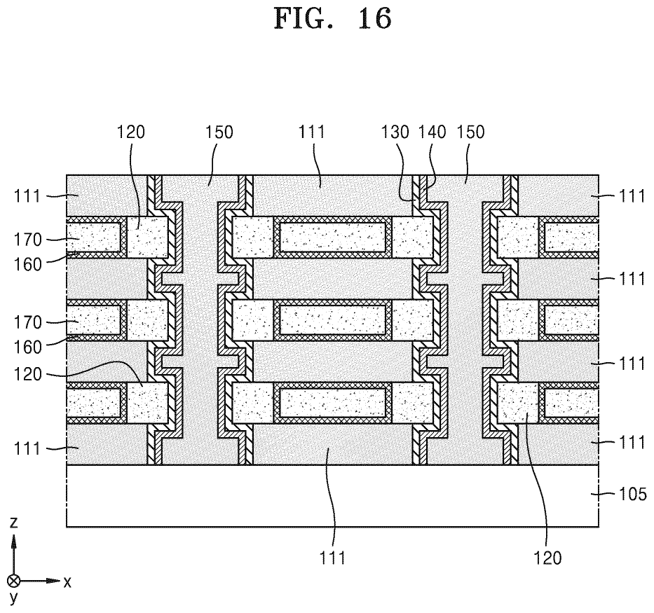

Referring to FIG. 16, a ferroelectric layer 160 and a gate electrode 170 are sequentially deposited on inner walls of the empty spaces 155 formed by removing the second mold layers 112. Accordingly, the ferroelectric layer 160 may be formed to contact the upper and lower surfaces and side surfaces of the gate electrode 170.

The ferroelectric layer 160 may include, for example, a fluorite-based material, a nitride-based material, or perovskite. The nitride-based material may include, for example, AlScN, and the perovskite may include, for example, PZT, BaTiO₃, PbTiO₃, and the like. However, it is not limited thereto.

The fluorite-based material may include, for example, oxide of at least one selected from Hf, Si, Al, Zr, Y, La, Gd, and Sr. As a specific example, the ferroelectric layer 160 may include at least one of hafnium oxide (HfO), zirconium oxide (ZrO), and hafnium-zirconium oxide (HfZrO). Hafnium oxide (HfO), zirconium oxide (ZrO), and hafnium-zirconium oxide (HfZrO) constituting the ferroelectric layer 160 may have a crystal structure of an orthorhombic crystal system. The ferroelectric layer 160 may further include, for example, at least one dopant selected from Si, Al, La, Y, Sr, and Gd. A thickness of the ferroelectric layer provided on the gate electrode may be in a range from about 3 nm to about 20 nm, but this is only an example.

The gate electrode 170 is formed on inner surfaces of the ferroelectric layer 160. The gate electrode 170 may include, for example, at least one of W, TiN, TaN, WN, NbN, Mo, Ru, Ir, RuO, IrO, and polysilicon. However, this is only an example.

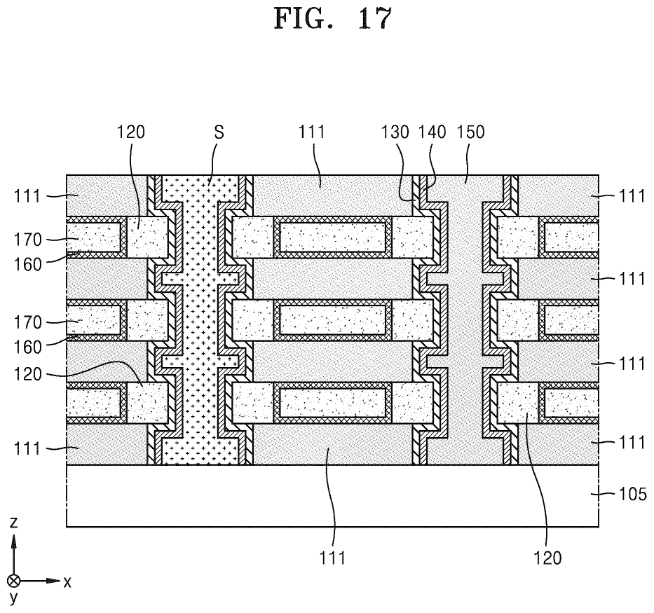

Referring to FIG. 17, one side and the other side of the filling insulating layer 150 are etched and removed in a direction perpendicular to the surface of the substrate 105 to form a source electrode S and a drain electrode D, and thus, the manufacture of a 3D ferroelectric memory device 100 is completed. One side and the other side of the filling insulating layer 150 are spaced apart from each other in a second direction (y-axis direction) parallel to the surface of the substrate 105. A plane of the 3D ferroelectric memory device 100 shown in FIG. 17 is shown in FIG. 1. The channel layer 140 extending in the second direction (y-axis direction) parallel to the surface of the substrate 105 between the source electrode S and the drain electrode D may form a channel of the ferroelectric field effect transistor.

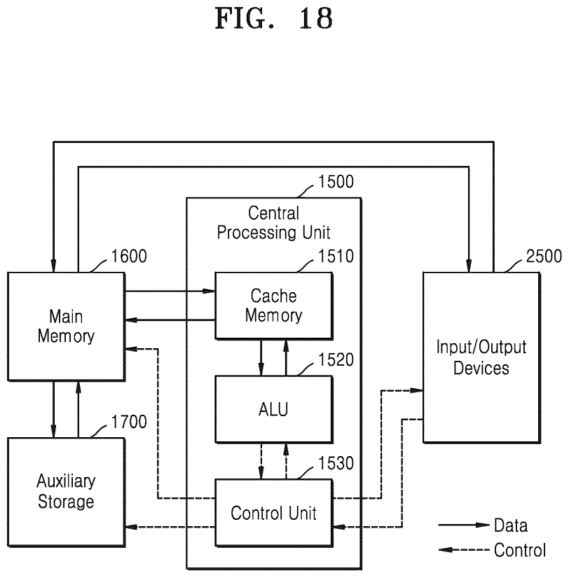

The 3D ferroelectric memory devices 100 and 200 described above may be used for a data storage in various electronic devices. FIG. 18 is a conceptual diagram schematically illustrating a device architecture applicable to an electronic device according to embodiments.

Referring to FIG. 18, a cache memory 1510, an ALU 1520, and a control unit 1530 may constitute a Central Processing Unit (CPU) 1500, and the cache memory 1510 may constitute a static random access memory (SRAM). Apart from the CPU 1500, a main memory 1600 and an auxiliary storage 1700 may be provided. The main memory 1600 may include a DRAM device, and the auxiliary storage 1700 may include the 3D ferroelectric memory devices 100 and 200 described above. In some cases, the device architecture may be implemented in a form in which computing unit devices and memory unit devices are adjacent to each other in one chip without distinguishing sub-units. One or more input/output devices 2500, such as a keyboard, mouse, touchscreen display, and the like may be operatively connected to the CPU 1500, main memory 1600, and auxiliary storage 1700.

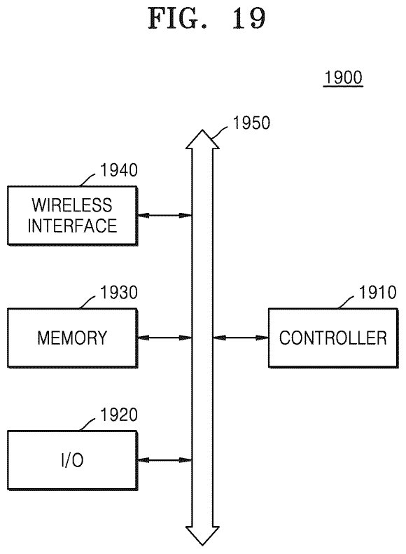

The 3D ferroelectric memory devices 100 and 200 described above may be used for memory in various electronic devices. For example, FIG. 19 is a block diagram of an electronic device according to an example embodiment.

Referring to FIG. 19, the electronic device 1900 may be a wireless communication device or a device capable of transmitting and/or receiving information in a wireless environment. The electronic device 1900 may include a controller 1910, an input/output device I/O 1920, a memory 1930, and a wireless interface 1940, which are connected to one another through a bus 1950.

The controller 1910 may include at least one of a microprocessor, a digital signal processor, or a processing device similar thereto. The input/output device 1920 may include at least one of a keypad, a keyboard, or a display. The memory 1930 may be used to store a command executed by the controller 1910. For example, the memory 1930 may be used to store user data. The electronic device 1900 may use the wireless interface 1940 to transmit/receive data through a wireless communication network. The wireless interface 1940 may include an antenna and/or a wireless transceiver. In some embodiments, the electronic device 1900 may be used in a communication interface protocol of a third-generation communication system, such as code division multiple access (CDMA), global system for mobile communications (GSM), North American digital cellular (NADC), extended-time division multiple access (E-TDMA), and/or wide band code division multiple access (WCDMA), a 4G (4th Generation) communication system such as 4G LTE, a 5G (5th Generation) communication system, a wired local area network (LAN), a wireless local area network (WLAN), such as Wi-Fi (Wireless Fidelity), a wireless personal area network (WPAN), such as Bluetooth, Wireless USB (Wireless Universal Serial Bus), Zigbee, Near Field Communication (NFC), Radio-frequency identification (RFID), and/or Power Line communication (PLC), etc. The memory 1930 of the electronic device 1900 may include any one of the 3D ferroelectric memory devices 100 and 200 described above.

According to according to an embodiment, because an intermediate electrode is provided to protrude from a side of an adjacent insulating layer, and a gate insulating layer and a channel layer are sequentially provided on the protruding intermediate electrode, a ratio of an area of the gate insulating layer in contact with the channel layer to an area of the ferroelectric layer in contact with the gate electrode may be increased, and a ratio of the capacitance of the gate insulating layer to the capacitance of the ferroelectric layer may be increased.

In this way, the intensity of an electric field applied to the gate insulating layer may be reduced by increasing a ratio of the capacitance of the gate insulating layer to the capacitance of the ferroelectric layer. Accordingly, an operating voltage may be reduced, an operating speed may be increased, and the reliability of the device may be improved by limiting and/or preventing deterioration of the gate insulating layer. In addition, on-current may be improved by increasing a width of the channel layer facing the intermediate electrode. Although the embodiments have been described above, it will be understood by those of ordinary skill in the art that various changes in form and details may be made therein without departing from the spirit and scope of the disclosure.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A three-dimensional (3D) ferroelectric memory device comprising:
a substrate;
a plurality of insulating layers stacked on the substrate;
a plurality of gate electrodes between the plurality of insulating layers;
a plurality of ferroelectric layers in contact with the plurality of gate electrodes;
a plurality of intermediate electrodes in contact with the plurality of ferroelectric layers, the plurality of intermediate electrodes protruding from side surfaces of the plurality of insulating layers;
a gate insulating layer in contact with the plurality of intermediate electrodes and the plurality of insulating layers; and
a channel layer in contact with the gate insulating layer.

2. The 3D ferroelectric memory device of claim 1, wherein
the plurality of gate electrodes are stacked in a direction perpendicular to the substrate, and
the plurality of gate electrodes each extend in a direction parallel to the substrate.

3. The 3D ferroelectric memory device of claim 2, wherein
each of the plurality of gate electrodes is electrically connected to a word line, and
each of the plurality of intermediate electrodes is a floating electrode.

4. The 3D ferroelectric memory device of claim 2, wherein
the plurality of intermediate electrodes protrude and extend from side surfaces of the plurality of insulating layers in a first direction parallel to the substrate.

5. The 3D ferroelectric memory device of claim 4, wherein
the plurality of ferroelectric layers include a corresponding ferroelectric layer,
the plurality of gate electrodes include a corresponding gate electrode in contact with the corresponding ferroelectric layer,
the plurality of intermediate electrodes include a corresponding intermediate electrode in contact with the corresponding ferroelectric layer, and
an area of the corresponding ferroelectric layer in contact with the corresponding gate electrode facing the corresponding intermediate electrode is less than an area of the gate insulating layer in contact with the channel layer facing the corresponding intermediate electrode.

6. The 3D ferroelectric memory device of claim 5, wherein
a length of the corresponding ferroelectric layer in contact with the gate electrode opposite to the corresponding intermediate electrode is less than a length of the gate insulating layer in contact with the channel layer opposite to the corresponding intermediate electrode.

7. The 3D ferroelectric memory device of claim 4, wherein
the plurality of ferroelectric layers include a corresponding ferroelectric layer,
the plurality of gate electrodes include a corresponding gate electrode,
the corresponding ferroelectric layer is on an upper surface of the corresponding gate electrode, a lower surface of the corresponding gate electrode, and one side of the corresponding gate electrode,
the lower surface of the corresponding gate electrode is parallel to the substrate, and
the one side of the corresponding gate electrode is perpendicular to the substrate.

8. The 3D ferroelectric memory device of claim 4, wherein
the plurality of ferroelectric layers include a corresponding ferroelectric layer,
the plurality of gate electrodes include a corresponding gate electrode,
the corresponding ferroelectric layer is on one side of the corresponding gate electrode, and
the one side of corresponding gate electrodes is perpendicular to the substrate.

9. The 3D ferroelectric memory device of claim 4, further comprising:
a source electrode and a drain electrode spaced apart from each other on the channel layer in a second direction,
the second direction is parallel to the substrate and perpendicular to the first direction, respectively.

10. The 3D ferroelectric memory device of claim 9, wherein
the source electrode is electrically connected to a source line, and the drain electrode is electrically connected to a bit line.

11. The 3D ferroelectric memory device of claim 1, wherein
the plurality of gate electrodes and the plurality of intermediate electrodes each independently include at least one of W, TiN, TaN, WN, NbN, Mo, Ru, Ir, RuO, IrO, and polysilicon.

12. The 3D ferroelectric memory device of claim 1, wherein the plurality of insulating layers includes at least one of SiO, SiOC, SiON, and SiN.

13. The 3D ferroelectric memory device of claim 1, wherein the plurality of ferroelectric layers include a fluorite-based material, a nitride-based material, or a perovskite material.

14. The 3D ferroelectric memory device of claim 1, wherein the gate insulating layer includes at least one of SiO, SiN, AlO, HfO, and ZrO.

15. The 3D ferroelectric memory device of claim 1, wherein the channel layer extends in a direction perpendicular to the substrate.

16. The 3D ferroelectric memory device of claim 15, wherein the channel layer commonly corresponds to the plurality of gate electrodes such that the channel layer faces the plurality of gate electrodes.

17. The 3D ferroelectric memory device of claim 15, wherein the channel layer includes a Group IV semiconductor, a Group III-V semiconductor, an oxide semiconductor, a nitride semiconductor, a nitride semiconductor, a 2D semiconductor material, a quantum dot, or an organic semiconductor.
